(19) United States
(12) Patent Application Publication
(10) Pub. No.: US 2023/0136720 A1
(43) Pub. Date: May 4, 2023

(54) SUBSTRATE SUPPORT, PLASMA PROCESSING APPARATUS, AND PLASMA PROCESSING METHOD

(71) Applicant: TOKYO ELECTRON LIMITED, TOKYO (JP)

(72) Inventors: Atsushi KAWABATA, Miyagi (JP); Shingo KOIWA, Miyagi (JP); Yasuhisa KUDO, Miyagi (JP)

(73) Assignee: TOKYO ELECTRON LIMITED, TOKYO (JP)

(21) Appl. No.: 17/976,513

(22) Filed: Oct. 28, 2022

(30) Foreign Application Priority Data
Oct. 29, 2021 (JP) 2021-178173
Sep. 29, 2022 (JP) 2022-156563

(51) Int. Cl. H01L 21/683; H01J 37/32

(52) U.S. Cl. CPC H01L 21/6833; H01J 37/32724; H01J 2237/2007

(57) ABSTRACT

There is provided a substrate support supporting a substrate comprising a base, a first ceramic layer on the base, and a second ceramic layer above the first ceramic layer. The first ceramic layer has a first base portion made of a first ceramic, and a plurality of heater electrodes included in the first base portion and for adjusting a temperature of the substrate. The second ceramic layer has a second base portion made of a second ceramic different from the first ceramic, and a chucking electrode included in the second base portion and for holding the substrate.

### CROSS-REFERENCE TO RELATED APPLICATIONS

This application claims priority to Japanese Patent Application Nos. 2021-178173 filed on Oct. 29, 2021 and 2022-156563 filed on Sep. 29, 2022, respectively, the entire contents of which are incorporated herein by reference.

### TECHNICAL FIELD

The present disclosure relates to a substrate support, a plasma processing apparatus and a plasma processing method.

### BACKGROUND

Japanese Laid-open Patent Publication No. 2015-084350 discloses a temperature control mechanism having multiple sets of a heater and a thyristor, wherein at least one set of the heater and the thyristor is provided corresponding to each of multiple areas which are provided by subdividing an electrostatic chuck having a substrate mounted thereon, a single power supply that supplies current to the heaters from the multiple sets of thyristors, and at least one set of filters provided in a power line supplying power to the multiple heaters from the single power supply and removing high-frequency power applied to the power supply.

### SUMMARY

A technique according to the present disclosure appropriately adjusts a temperature of a substrate supported on a substrate support to maintain electrostatic adsorption even in a high-temperature range.

In accordance with an aspect of the present disclosure, there is provided a substrate support, comprising a base, a first ceramic layer on the base, and a second ceramic layer above the first ceramic layer, wherein the first ceramic layer has a first base portion made of a first ceramic, and a plurality of heater electrodes included in the first base portion and for adjusting a temperature of the substrate, and wherein the second ceramic layer has a second base portion made of a second ceramic different from the first ceramic, and a chucking electrode included in the second base portion and for holding the substrate.

### BRIEF DESCRIPTION OF THE DRAWINGS

FIG. 1 is an explanatory diagram schematically illustrating a configuration of a plasma processing system according to an exemplary embodiment.

FIG. 2 is a cross-sectional view illustrating an example of a configuration of a plasma processing apparatus according to an exemplary embodiment.

FIG. 3 is a cross-sectional view illustrating an example of a substrate support according to an exemplary embodiment.

FIG. 4 is a plan view illustrating an example of a constitution of multiple areas of a first base according to an exemplary embodiment.

### DETAILED DESCRIPTION

In a manufacturing process of a semiconductor device, desired processing is performed to a semiconductor substrate (hereinafter referred to as “substrate”) in a state in which the semiconductor substrate is mounted on a substrate support. A substrate mounted on a ceramic member constituting a substrate support surface of the substrate support is adjusted to an appropriate temperature according to the manufacturing process. Japanese Laid-open Patent Publication No. 2015-084350 proposes a substrate support configured to include a heater electrode jointly with a chucking electrode in the ceramic member and have both fixation support of the substrate on the ceramic member and temperature adjustment of the substrate. In particular, Japanese Laid-open Patent Publication No. 2015-084350 discloses subdividing the heater electrode provided inside the substrate support and locally adjusting a temperature of each of multiple areas.

The fixation support of the substrate in the ceramic member is performed by applying voltage to the substrate support surface by the chucking electrode embedded in the ceramic member. When the substrate support surface is applied with the voltage by the chucking electrode, a potential difference is generated between the substrate support surface and a substrate polarized with an electric charge opposite to the electric charge of the substrate support surface to generate adsorptive force by coulomb force. The ceramic member constituting the substrate support surface is constituted by ceramics which is a dielectric, but this is to have a dielectric that efficiently makes the application of the voltage by the chucking electrode contribute to adsorptive power and have an insulation that insulates the substrate and the substrate support surface so that current does not flow between the substrate and the substrate support surface. Regarding insulation, if the current flows between the substrate and the substrate support surface, the potential difference between the substrate and the substrate support surface decreases, and the adsorption force thus decreases.

However, in recent years, in a plasma etching device, etching a film of the substrate including metal is required to be performed with high precision as a next-generation semiconductor device. For the implementation, in the substrate support, it is required to adjust the substrate in a high-temperature range higher than 200C (hereinafter, just referred to as high-temperature range) or to uniformly or locally adjust an in-plane temperature of the substrate even in the high-temperature range. Further, in the present disclosure, uniformly adjusting the temperature of the substrate refers to a case where there is no difference in in-plane temperature in an entire area of the substrate or the difference is small enough to be ignored. Further, in the present disclosure, locally adjusting the temperature of the substrate refers to a case where, by adjusting a predetermined part of the substrate to a desired temperature, there is no difference in the predetermined part or the difference is small enough to be ignored.

The substrate support disclosed in Japanese Laid-open Patent Publication No. 2015-084350 enables uniformly or locally adjusting the temperature in a conventional etching temperature, i.e., a temperature range lower than 200° C., but does not assume the temperature adjustment for the high-temperature range and may not be adopted in the high-temperature range. Specifically, according to the examination of the present inventor, if the temperature of the substrate support disclosed in Japanese Laid-open Patent Publication No. 2015-084350 is adjusted to a high-temperature range, the volume resistance of the ceramic member that constitutes the substrate support surface decreases and the insulation thus decreases. Further, it is known that the ceramic member in which the insulation decreases does not maintain electrostatic adsorption because the adsorption force between the substrate and the substrate support surface decreases due to the aforementioned reason, and a problem such as substrate deviation occurs. Therefore, a substrate support which maintains the electrostatic adsorption even in the high-temperature range and is capable of uniformly or locally adjusting the in-plane temperature of the substrate is required.

Therefore, the technology according to the present disclosure as a substrate support capable of fixing and supporting the substrate by the electrostatic adsorption and adjusting the temperature provides a substrate support which maintains the electrostatic adsorption even in the high-temperature range and is capable of uniformly or locally adjusting the in-plane temperature of the substrate.

Hereinafter, a configuration of a substrate processing apparatus according to an exemplary embodiment will be described with reference to drawings. Further, in the present specification, the same reference numerals are given to elements having substantially the same functional configuration, so a redundant description will be omitted.

<Plasma Processing System>

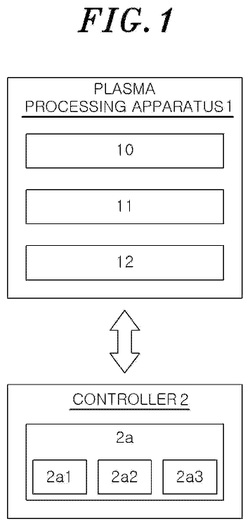

FIG. 1 is an explanatory diagram schematically illustrating a configuration of a plasma processing system according to an exemplary embodiment. In an exemplary embodiment, a plasma processing system includes a plasma processing apparatus 1 and a controller 2. The plasma processing apparatus 1 includes a plasma processing chamber 10, a substrate support portion 11, and a plasma generation portion 12. The plasma processing chamber 10 has a plasma processing space. Further, the plasma processing chamber 10 includes at least one gas supply port for supplying at least one processing gas to the plasma processing space and at least one discharge port for discharging gas from the plasma processing space. The gas supply port is connected to a gas supply portion 20 to be described below and the gas discharge port is connected to an exhaust system 40 to be described below. The substrate support portion 11 is disposed in the plasma processing space, and has a substrate support surface for supporting a substrate.

The plasma generation portion 12 is configured to generate plasma from at least one processing gas supplied in the plasma processing space. The plasma formed in the plasma processing space may be capacitively coupled plasma (CCP), inductively coupled plasma (ICP), electron-cyclotron-resonance plasma (ECR plasma), helicon wave plasma (HWP), or surface plasma (SWP). Further, various types of plasma generation portions may be used, which include an alternating current (AC) plasma generation portion and a direct current (DC) plasma generation portion. In an exemplary embodiment, an AC signal (AC power) used in the AC plasma generation portion has a frequency in a range of 100 kHz to 10 GHz. Therefore, the AC signal includes a radio frequency (RF) signal and a microwave signal. In an exemplary embodiment, the RF signal has a frequency in a range of 200 kHz to 150 MHz.

The controller 2 processes a computer executable command which allows the plasma processing apparatus 1 to execute various processes described in the present disclosure. The controller 2 may be configured to control each element of the plasma processing apparatus 1 so as to execute various processes described herein. In an exemplary embodiment, a part or the entirety of the controller 2 may be included in the plasma processing apparatus 1. The controller 2 may include, for example, a computer 2a. The computer 2a may include a central processing unit (CPU) 2a1, a memory portion 2a2, and a communication interface 2a3, for example. The CPU 2a1 may be configured to perform various control operations based on a program stored in the memory portion 2a2. The storage portion 2a2 may include a random access memory (RAM), a read only memory (ROM), a hard disk drive (HDD), a solid state drive (SSD), or a combination thereof. The communication interface 2a3 may communicate with the plasma processing apparatus 1 through a communication line such as local area network (LAN), etc.

<Plasma Processing Apparatus>

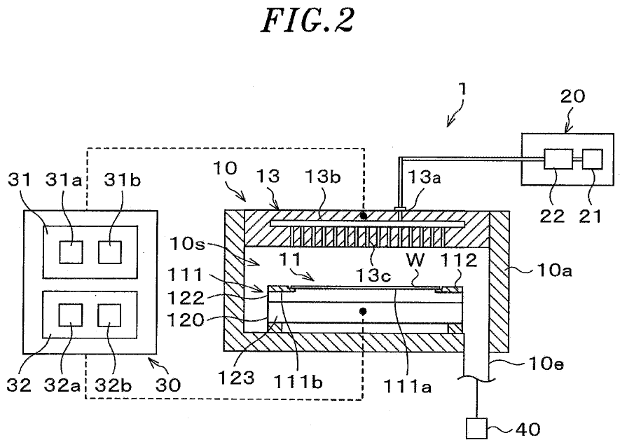

Next, as an example of the plasma processing apparatus 1, an example of a configuration of a capacitively coupled plasma processing apparatus will be described by using FIG. 2. The plasma processing apparatus 1 includes a plasma processing chamber 10, a gas supply portion 20, a power supply 30, and an exhaust system 40. Further, the plasma processing apparatus 1 includes a substrate support portion 11 and a gas introduction portion. The gas introduction portion is configured to introduce at least one processing gas into the plasma processing chamber 10. The gas introduction portion includes a shower head 13. The substrate support portion 11 is disposed in the plasma processing chamber 10. The shower head 13 is disposed above the substrate support portion 11. In an exemplary embodiment, the shower head 13 constitutes at least a part of a ceiling of the plasma processing chamber 10. The plasma processing chamber 10 includes the shower head 13, a side wall 10a of the plasma processing chamber 10, and a plasma processing space 10s defined by the substrate support portion 11. The side wall 10a is grounded. The shower head 13 and the substrate support portion 11 are electrically insulated from a housing of the plasma processing chamber 10.

The substrate support portion 11 includes a substrate support 111 and a ring assembly 112. The substrate support 111 has a central area 111a for supporting the substrate (wafer) W and a ring-shaped area 111b (ring support surface) 111b for supporting the ring assembly 112. The ring-shaped area 111b of the substrate support 111 surrounds the central area 111a of the substrate support 111 in a plan view. The substrate W is disposed on the central area 111a (substrate support surface 114) of the substrate support 111, and the ring assembly 112 is disposed on the ring-shaped area 111b of the substrate support 111 to surround the substrate W on the substrate support surface 114. In an exemplary embodiment, the substrate support 111 includes a base 120 and an electrostatic chuck 122. The base 120 includes a conductive member 123. The conductive member 123 of the base 120 serves as a lower electrode. The electrostatic chuck 122 is disposed on the base 120. An upper surface of the electrostatic chuck 122 has the substrate support surface 114. Configurations of the base 120 and the electrostatic chuck 122 will be described below in detail. The ring assembly 112 includes one or a plurality of ring-shaped members. Further, the substrate support portion 11 may include a temperature control module configured to control at least one of the electrostatic chuck 122, the ring assembly 112, and the substrate W to a target temperature. The temperature control module may include a heater, a heating medium, a path, and a combination thereof. In the path, a heating fluid such as brine or gas flows. Further, the substrate support portion 11 may include a heating gas supply portion configured to supply heating gas between a back surface of the substrate W and the substrate support surface 114.

The shower head 13 is configured to introduce at least one processing gas from the gas supply portion 20 into the plasma processing space 10s. The shower head 13 includes at least one gas supply port 13a, at least one gas diffusion chamber 13b, and a plurality of gas introduction ports 13c. The processing gas supplied to the gas supply port 13a is introduced into the plasma processing space 10s from the plurality of gas introduction ports 13c by passing through the gas diffusion chamber 13b. Further, the shower head 13 includes the conductive member. The conductive member of the shower head 13 serves as an upper electrode. Further, the gas introduction portion may include one or a plurality of side gas injectors (SGI) mounted on one or a plurality of openings formed on the side wall 10a in addition to the shower head 13.

The gas supply portion 20 may include at least one gas source 21 and at least one flow rate controllers 22. In an exemplary embodiment, the gas supply portion 20 is configured to supply at least one processing gas to the shower head 13 from the gas sources 21 corresponding to each processing gas, through the flow controllers 22 corresponding thereto, respectively. Each flow rate controller 22 may include, for example, a mass-flow controller or a pressure control type flow rate controller. Further, the gas supply portion 20 may include at least one flow rate modulation device which modulates or pulses the flow rate of at least one processing gas.

The power supply 30 includes an RF power supply 31 coupled to the plasma processing chamber 10 through at least one impedance matching circuit. The RF power supply 31 is configured to supply at least one RF signal (RF power) such as a source RF signal and a bias RF signal to the conductive member of the substrate support portion 11 and/or the conductive member of the shower head 13. Therefore, plasma is formed from at least one processing gas supplied to the plasma processing space 10s. Therefore, the RF power supply 31 may serve as at least a part of the plasma generation portion 12. Further, by supplying the bias RF signal to the conductive member of the substrate support portion 11, a bias potential may be generated on the substrate W and ion components in the generated plasma may be drawn to the substrate W.

In an exemplary embodiment, the RF power supply 31 includes a first RF generation portion 31a and a second RF generation portion 31b. The first RF generation portion 31a is configured to be coupled to the conductive member of the substrate support portion 11 and/or the conductive member of the shower head 13 through at least one impedance matching circuit, and to generate a source RF signal (source RF power) for plasma generation. In an exemplary embodiment, the source RF signal has a frequency in a range of 13 MHz to 150 MHz. In an exemplary embodiment, the first RF generation portion 31a may be configured to generate a plurality of source RF signals having different frequencies. One or a plurality of source RF signals which are generated are supplied to the conductive member of the substrate support portion 11 and/or the conductive member of the shower head 13. The second RF generation portion 31b is configured to be coupled to the conductive member of the substrate support portion 11 through at least one impedance matching circuit, and to generate the bias RF signal (bias RF power). In an exemplary embodiment, the bias RF signal has a lower frequency than the source RF signal. In an exemplary embodiment, the bias RF signal has a frequency in a range of 400 kHz to 13.56 MHz. In an exemplary embodiment, the second RF generation portion 31b may be configured to generate a plurality of bias RF signals having different frequencies. One or a plurality of bias RF signals generated is supplied to the conductive member of the substrate support portion 11. Further, in various exemplary embodiments, at least one of the source RF signal and the bias RF signal may be pulsed.

Further, the power supply 30 may include the DC power supply 32 coupled to the plasma processing chamber 10. The DC power supply 32 includes a first DC generation portion 32a and a second DC generation portion 32b. In an exemplary embodiment, the first DC generation portion 32a is configured to be connected to the conductive member of the substrate support portion 11 and generate a first DC signal. The generated first DC signal is applied to the conductive member of the substrate support portion 11. In an exemplary embodiment, the first DC signal may be applied to an electrode different from the electrode in the electrostatic chuck 122. In an exemplary embodiment, the second DC generation portion 32b is configured to be connected to the conductive member of the shower head 13 and generate a second DC signal. The generated second DC signal is applied to the conductive member of the shower head 13. In various exemplary embodiments, the first and second DC signals may be pulsed. Further, the first and second DC generation portions 32a and 32b may be provided in addition to the RF power supply 31 or the first DC generation portion 32a may be provided instead of the second RF generation portion 31b.

The exhaust system 40 may be connected to a gas outlet 10e provided on a bottom of the plasma processing chamber 10, for example. The exhaust system 40 may include a pressure adjustment valve and a vacuum pump. By the pressure adjustment valve, pressure in the plasma processing space 10s is adjusted. The vacuum pump may include a turbo molecule pump, a dry pump, or a combination thereof.

<Substrate Support>

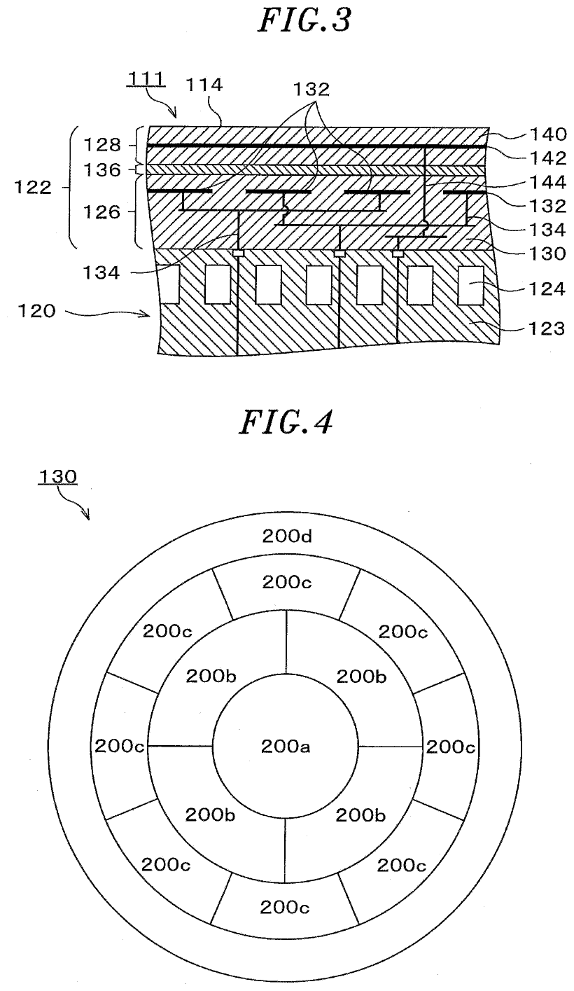

Next, the substrate support 111 according to the exemplary embodiment will be described in detail. FIG. 3 is an explanatory diagram schematically illustrating a configuration of a substrate support 111 according to an exemplary embodiment. Further, FIG. 3 illustrates a part of a central area 111a of the substrate support 111, and the other portion of the central area 111a and the ring-shaped area 111b, and a lower portion of the base 120 are not illustrated. However, the other portion of the central area 111a and the ring-shaped area 111b have a similar configuration to some illustrated components.

In FIG. 3, the substrate support 111 includes the base 120 and the electrostatic chuck 122. The conductive member 123 of the base 120 uses aluminum as a material, and includes a cooling path 124 inside the base 120. The electrostatic chuck 122 has a first ceramic layer 126 provided above the base 120 and a second ceramic layer 128 provided above the first ceramic layer 126. Further, as the conductive member 123 of the base 120, an appropriate metallic material may be used in addition to aluminum.

The first ceramic layer 126 is mounted on the base 120. The method of mounting is not particularly limited, and the first ceramic layer 126 may be fixed and mounted using a known means. In addition, the first ceramic layer 126 includes a first base portion 130 which is a sintered body of the first ceramic, a plurality of heater electrodes 132, and a multi-layered electrical wiring 134 provided on multiple layers and connected to the plurality of heater electrodes 132. The first base portion 130 is configured to include the plurality of heater electrodes 132, the multi-layered electrical wirings 134 provided on multiple layers and connected to the plurality of heater electrodes 132, and an electrical wiring 144 connected to the chucking electrode in a second ceramic layer 128 to be described below. Further, in the present disclosure, “include” means, for example, a state in which one component includes another component includes a state in which the another component is buried in the component and not exposed to the outside, and a state in which a part of the another component is buried inside the component and the other portion of the another component is exposed to the outside.

The second ceramic layer 128 is provided above the first ceramic layer 126, and in the exemplary embodiment, the second ceramic layer 128 is bonded to the first ceramic layer 126 with an adhesive layer 136 made of an inorganic adhesive, which is interposed therebetween. Further, the second ceramic layer 128 includes a second base portion 140 which is a sintered body of a second ceramic, and a chucking electrode 142. The second base portion 140 is configured to include the chucking electrode 142 and the electrical wiring 144 connected to the chucking electrode 142. In the exemplary embodiment, the chucking electrode 142 may adopt an HV electrode and provides electrostatic adsorption between the substrate support surface 114 and a substrate W which is not illustrated by applying DC voltage to the chucking electrode 142.

The multi-layered electrical wiring 134 connected to the heater electrode 132, and the electrical wiring 144 connected to the chucking electrode 142 are connected to a power supply which is not illustrated through the inside or the outside of the base 120. As a result, the base 120 is configured to include the multi-layered electrical wiring 134 and the electrical wiring 144.

Here, in the substrate support 111 configured as above, an example of a manufacturing method of the electrostatic chuck 122 will be described below.

A manufacturing method of the first ceramic layer 126 is capable of adopting a green sheet method. Specifically, it is possible to manufacture the first ceramic layer 126 by stacking and sintering a plurality of green sheets respectively constituted by first ceramics separately sintered. Further, the green sheet is acquired by forming a material using a ceramic as a main ingredient in a sheet shape. The ceramic layer as a multi-layered structure constituting the electrostatic chuck may be formed by sintering the green sheet. As described above, since the first base portion 130 includes the plurality of heater electrodes 132, and the multi-layered electrical wirings 134 connected thereto, a green sheet method is very suitable for manufacturing the first ceramic layer 126 having such a complicated internal structure. Specifically, when the multi-layered structure is formed by stacking the plurality of green sheets by the green sheet method, the green sheets may be stacked so that the heater electrode or the electrical wiring is provided between respective layers. Therefore, it is preferable that the first ceramic as the material is a ceramic applicable to the green sheet method, and adopts alumina in the exemplary embodiment.

A manufacturing method of the second ceramic layer 128 is capable of adopting a hot press method. As the second ceramic which is the material, alumina at 99.95% or more as a mass percent concentration, and high-purity alumina in which a porous rate is 0.1% or less may be used. Here, the porous rate is a value representing a ratio of a total sum of areas of all porosities included in an observation visual field to an area of the observation visual field of the corresponding cross section when the cross section of the second ceramic layer 128 is observed. The hot press method is used for the high-purity alumina, and the second ceramic layer 128 may be manufactured, which has high volume resistance even in the high-temperature area, specifically, volume resistance of 1×10¹⁶Ω or more at a room temperature or more and a temperature of 350° C. or less, and a dielectric constant of 10 to 11.

The first ceramic layer 126 and the second ceramic layer 128 manufacturing as such are bonded through the adhesive layer 136 made of, for example, the inorganic adhesive. A reason for using the inorganic adhesive may be that thermal resistance is low. The reason is that since heat is input into the second ceramic layer 128 from the heater electrode 132 of the first ceramic layer 126, the adhesive layer 136 provided therebetween preferably has low thermal resistance. Further, it is preferable to use the inorganic adhesive because deterioration of the adhesive layer 136 is small even when the adhesive layer 136 is exposed to plasma on an outer periphery of the substrate support 111.

An advantage of configuring the substrate support 111 according to the exemplary embodiment as above will be described below. As described above, in the electrostatic chuck 122 in the related art, the volume resistance of the ceramic member constituting the substrate support surface 114 decreases in the high-temperature range, so current may flow between the substrate support surface 114 and the substrate W. In this case, the electrostatic adsorption is not maintained, and the substrate W is deviated from a desired position, so there is a concern about exerting a bad influence on a subsequent process.

In order to hold the electrostatic adsorption between the substrate W and the substrate support surface 114 in the high-temperature range, using a ceramic member having high volume resistance in the high-temperature range so that the current does not flow between the substrate W and the substrate support surface 114 is considered. It is possible to manufacture the ceramic member having the high volume resistance in the high-temperature range may be manufactured by using the hot press method for the high-purity alumina as described above. Meanwhile, it is preferable to manufacture a ceramic member in which the plurality of heater electrodes 132 is included in the high-purity alumina by the green sheet method.

In this regard, according to a result in which the present inventor further repeats the examination, it is learned that the first ceramic layer 126 including the plurality of heater electrodes 132 is manufactured by the green sheet method, the second ceramic layer 128 including the chucking electrode 142 and having the high volume resistance in the high-temperature range is manufactured by the hog press method, and two types of layers are bonded to form the electrostatic chuck 122 that solves the problem. That is, the electrostatic chuck 122 according to the exemplary embodiment enables uniformly or locally adjusting the temperature in the high-temperature range by the first ceramic layer 126 including the plurality of heater electrodes 132, and enables maintaining the electrostatic adsorption in the high-temperature by the second ceramic layer 128 including the chucking electrode 142 and having the volume resistance in the high-temperature range. Further, when different ceramic materials are bonded, if the ceramic materials are deformed upon heating or cooling, a warpage accompanied by a different in thermal coefficient of the ceramic materials is concerned. In this regard, in the electrostatic chuck 122 according to the exemplary embodiment, since both the first ceramic layer 126 and the second ceramic layer 128 use alumina as the main material, the difference in thermal expansion of the first ceramic layer 126 and the second ceramic layer 128 may be suppressed to be small, so the concern is resolved.

According to the above exemplary embodiment, temperatures of the plurality of heater electrodes 132 may be controlled independently by the multi-layered electrical wiring 134. Further, provided is the substrate support 111 in which the first ceramic layer 126 including the plurality of heater electrodes 132 enables uniformly or locally adjusting the temperature of the substrate W even in the high-temperature range, and the second ceramic layer 128 including the chucking electrode 142 and having the high volume resistance in the high-temperature range enables maintaining the electrostatic adsorption of the substrate W in the high-temperature range.

In an exemplary embodiment, the first base portion 130 includes a plurality of areas 200 in plan view, and the plurality of heater electrodes 132 is disposed every the plurality of areas 200. That is, one or two or more heater electrodes 132 are provided to correspond to one area 200, and each of the heater electrodes 132 adjusts the temperature of each of the plurality of corresponding areas 200.

FIG. 4 illustrates an example in which the number, shapes, and arrangement of multiple areas 200 are very suitable in the first base portion 130 as a plan view when the first base portion 130 according to an exemplary embodiment is viewed from the top. In FIG. 4, each area surrounded by a solid line is one area 200. The first base portion 130 includes a plurality of areas 200 of which shapes and arrangement rotatably symmetric to a circumference around the center of the first base portion 130. In the example illustrated in FIG. 4, the plurality of areas 200 are rotatably symmetric to each other at 90 degrees around the center of the first base portion 130. Specifically, the plurality of areas 200 includes one first area 200a positioned and provided at the center of the first base portion 130, four second areas 200b positioned and provided at an outer periphery side of the first area 200a, eight third areas 200c positioned at the outer periphery side of the second area 200b, and one fourth area 200d positioned and provided at an outer periphery of the third area 200c, i.e., the outer periphery of the first base portion 130. The heater electrode 132 is provided to correspond to each of the plurality of areas 200. In an exemplary embodiment, the heater electrode 132 having a shape which is the same as the shape of one area 200 is provided to correspond to one area 200.

The first base portion 130 includes the plurality of areas 200 on the plan view, and the plurality of heater electrodes are arranged every the plurality of areas 200 to adjust the temperature of each of the plurality of areas 200 by the plurality of heater electrodes. This enables more efficiently locally adjusting the temperature to more uniformly adjust the in-plane temperature of the substrate W.

<Plasma Processing Method>

Next, a plasma processing method using the plasma processing apparatus 1 including the substrate support 111 configured as such will be described below. As plasma processing, for example, etching processing or film-forming processing is performed.

First, the substrate W is loaded to the inside of the plasma processing chamber 10, and the substrate W is mounted on the electrostatic chuck 122. Thereafter, by applying the DC voltage to the chucking electrode 142 of the electrostatic chuck 122, the substrate W is electrostatically adsorbed and held on the electrostatic chuck 122 by Coulomb force.

Next, a partial area or an entire area of the substrate W is adjusted to a desired temperature by at least one heater electrode (any one or all heater electrodes) of the plurality of heater electrodes 132 of the first ceramic layer 126. Further, in adjusting the temperature, the temperature of the partial area or the entire area of the substrate W may be adjusted to the high-temperature range. Further, after the substrate W is loaded, the inside of the plasma processing chamber 10 is decompressed to a desired vacuum degree by the exhaust system 40.

Next, processing gas is supplied from the gas supply portion 20 to the plasma processing space 10s through the shower head 13. Further, source RF power for plasma generation is supplied to the conductive member of the substrate support portion 11 and/or the conductive member of the shower head 13 by the first RF generation portion 31a of the first RF power 31. In addition, the processing gas is excited to generate the plasma. In this case, a bias RF signal for ion introduction may be supplied by the second RF generation portion 31b. In addition, by an action of the generated plasma, the plasma processing is performed for the substrate W.

The plasma processing method may be executed by controlling each component of the plasma processing apparatus 1 to execute a desired process by the controller 2.

According to the plasma processing method, the substrate W is mounted on the substrate support 111 configured as above to adjust the temperature of the partial area or the entire area of the substrate W and the plasma processing may be performed while the electrostatic adsorption is maintained even in the high-temperature range. Therefore, the plasma processing of the substrate W in the high-temperature range may be performed with high precision, and in particular, plasma processing of a film of the substrate W including metal may be performed with high precision.

It should be considered that the disclosed exemplary embodiment as an example is not limited in all points. Further, the exemplary embodiment may be omitted, substituted, and changed as various forms without departing from the appended claims, a configuration example which belongs to a technical scope of the present disclosure to be described below, and the spirit.

For example, a material and a manufacturing method of the substrate support 111 are not limited to the exemplary embodiment. That is, the first ceramic layer 126 is manufactured by the green sheet method by using alumina as the first ceramic, but the material and the manufacturing method may be substituted and changed to a known material and a known manufacturing method, which are capable of including the plurality of heater electrodes 132 and the multi-layered electrical wiring 134 connected to the plurality of heater electrodes 132 therein. Further, the second ceramic layer 128 is manufactured by the hot press method by using high-purity alumina as the second ceramic, but the material and the manufacturing method may be substituted and changed to a known material and a known manufacturing method, which are capable of including the chucking electrodes 142 and the wiring connected to the chucking electrodes 142 therein and capable of having the high volume resistance enabling maintaining the electrostatic adsorption in the high-temperature range. Further, in the cases, when the first ceramic layer 126 and the second ceramic layer 128 are manufactured, a combination in which the difference in thermal expansion between the first ceramic layer 126 and the second ceramic layer 128 becomes 5 ppm or less is preferable. When the difference in thermal expansion between the first ceramic layer 126 and the second ceramic layer 128 is 5 ppm or less, even in a case where the first ceramic layer 126 and the second ceramic layer 128 are heated or cooled, and thereby deformed, the warpage or the like between the first ceramic layer 126 and the second ceramic layer 128 may be suppressed at least in a temperature range of the room temperature to 400° C. since the first ceramic layer 126 and the second ceramic layer 128 are deformed by an expansion rate or a shrinkage rate at the same degree. As a result, the first ceramic and the second ceramic may adopt ceramics using the same ceramic as the main ingredient.

Further, the second ceramic layer 128 may have a volume resistance of 1×10¹⁶Ω or more at an operating environment temperature (e.g., the room temperature or more and a temperature of 350° C. or less) in order to exhibit an effect of the maintaining the electrostatic adsorption in the high-temperature range. In this case, the second ceramic may adopt a ceramic having higher volume resistance than the first ceramic. Further, in the exemplary embodiment, high-purity alumina, which includes alumina of 99.95% and has a porous rate which is 0.1% or less, is used as the second ceramic but is not limited thereto. A ceramic material, which may have the volume resistance in the operating environment temperature, may be applicable. The second ceramic may adopt a ceramic which has higher purity than the first ceramic.

Further, in the exemplary embodiment, the inorganic adhesive is used as the adhesive layer 136 bonding the first ceramic layer 126 and the second ceramic layer 128, but is not limited thereto. As an adhesive means applicable to the adhesive layer 136, for example, an organic adhesive may be used. In this case, the organic adhesive preferably has at least low thermal resistance and plasma resistance so that deterioration is small even when the organic adhesive is exposed to the plasma. Further, it is possible to bond the first ceramic layer 126 and the second ceramic layer 128 by a diffusion bonding method, and in this case, the adhesive layer 136 may not be provided.

Further, in the plasma processing method, the temperature is adjusted to the high-temperature range, but the plasma processing may be executed even in a temperature range in which a part or the entirety of the substrate W does not reach 200° C. Further, the temperature adjustment may be a higher temperature, and specifically, the plasma processing may be performed by adjusting the temperature of the partial area or the entire area of the substrate W becomes 300° C. or more.

Further, for example, a constitution requirement of the exemplary embodiment may be an arbitrary combination. In the arbitrary combination, an action and an effect for each constitution requirement according to the combination are naturally obtained, and another action and another effect which are apparent to those skilled in the art are obtained from the disclosure of the present specification.

Further, the effect disclosed in the present specification is descriptive or exemplary anywhere, and is not limited. That is, the technology according to the present disclosure has the effect or another effect which is apparent those skilled in the art from the disclosure of the present specification instead of the effect.

For example, the present disclosure includes the following exemplary embodiment.

(Additional Statement 1)

A substrate support, comprising:

a base;

a first ceramic layer on the base; and

a second ceramic layer above the first ceramic layer,

wherein the first ceramic layer has

a first base portion made of a first ceramic, and

a plurality of heater electrodes included in the first base portion and for adjusting a temperature of the substrate, and

wherein the second ceramic layer has

a second base portion made of a second ceramic different from the first ceramic, and

a chucking electrode included in the second base portion and for holding the substrate.

(Additional Statement 2)

The substrate support of additional statement 1, wherein the first base portion includes a plurality of areas, and

at least one of the plurality of heater electrodes are arranged in each of the plurality of areas.

(Additional Statement 3)

The substrate support of additional statement 1 or 2, wherein the first ceramic layer includes a plurality of multi-layered electrical wirings included in the first base portion and connected to the plurality of heater electrodes, respectively.

(Additional Statement 4)

The substrate support of any one of additional statements 1 to 3, wherein the first base portion is a multi-layered structure in which a plurality of ceramic layers are stacked, and

at least one heater electrode is disposed between respective layers of the plurality of ceramic layers.

(Additional Statement 5)

The substrate support of additional statement 4, wherein the plurality of ceramic layers is a sintered body of a plurality of green sheets.

(Additional Statement 6)

The substrate support of any one of additional statements 1 to 5, wherein the second base portion is a sintered body of the second ceramic.

(Additional Statement 7)

The substrate support of any one of additional statements 1 to 6, wherein the second ceramic has higher volume resistance than the first ceramic.

(Additional Statement 8)

The substrate support of any one of additional statements 1 to 7, comprising an adhesive layer including an inorganic adhesive and disposed between the first ceramic layer and the second ceramic layer.

(Additional Statement 9)

The substrate support of any one of additional statements 1 to 8, wherein the first ceramic and the second ceramic have the same ceramic as a main ingredient.

(Additional statement 10)

The substrate support of any one of additional statements 1 to 9, wherein the second ceramic has higher purity than the first ceramic.

(Additional Statement 11)

The substrate support of any one of additional statements 1 to 10, wherein the second base portion has volume resistance of 1×10¹⁶Ω or more at a room temperature or more and 350° C. or less.

(Additional statement 12)

The substrate support of any one of additional statements 1 to 11, wherein the second ceramic includes alumina at a mass percentage concentration of 99.95% or more.

(Additional Statement 13)

The substrate support of any one of additional statements 1 to 12, wherein a dielectric constant of the second ceramic is 10 to 11.

(Additional statement 14)

The substrate support of any one of additional statements 1 to 13, wherein a difference in thermal expansion coefficients between the first base portion and the second base portion is 5 ppm or less.

(Additional Statement 15)

The substrate support of any one of additional statements 1 to 14, wherein the second ceramic has a porous rate of 0.1% or less.

(Additional Statement 16)

A plasma processing apparatus processing a substrate, comprising:

a chamber; and

a substrate support inside the chamber,

wherein the substrate support has

a base,

a first ceramic layer on the base, and

a second ceramic layer above the first ceramic layer,

wherein the first ceramic layer has

a first base portion made of a first ceramic, and

a plurality of heater electrodes included in the first base portion and for adjusting a temperature of the substrate, and

wherein the second ceramic layer has

a second base portion made of a second ceramic different from the first ceramic, and

a chucking electrode included in the second base portion and for holding the substrate.

(Additional Statement 17)

The plasma processing apparatus of additional statement 16, wherein the first base portion includes a plurality of areas, and

at least one of the plurality of heater electrodes are arranged in each of the plurality of areas.

(Additional Statement 18)

The plasma processing apparatus of additional statement 16 or 17, wherein the first ceramic layer includes a plurality of multi-layered electrical wirings included in the first base portion and connected to the plurality of heater electrodes, respectively.

(Additional Statement 19)

The plasma processing apparatus of additional statement 18, comprising at least one power supply connected to the plurality of heater electrodes through the plurality of multi-layered electrical wirings,

wherein each of the plurality of heater electrodes is configured to perform temperature control independently.

(Additional statement 20)

A plasma processing method processing a substrate using a plasma processing apparatus, wherein the plasma processing apparatus includes

a chamber, and

a substrate support disposed inside the chamber,

the substrate support has
a base,
a first ceramic layer on the base, and
a second ceramic layer above the first ceramic layer,

the first ceramic layer has
a first base portion made of a first ceramic, and
a plurality of heater electrodes included in the first base portion and for adjusting a temperature of the substrate, and

the second ceramic layer has
a second base portion made of a second ceramic different from the first ceramic, and
a chucking electrode included in the second base portion and for holding the substrate,

wherein the plasma processing method includes:

disposing the substrate on a substrate support surface of the substrate support;

chucking the substrate on the substrate support surface by using the chucking electrode;

heating the second ceramic layer and the substrate by using at least one of the plurality of heater electrodes to adjust a temperature of a partial area or an entire area of the substrate to 300° C. or more; and

plasma-processing the partial area or the entire area of the substrate of which the temperature is adjusted.

1. A substrate support, comprising:
a base;
a first ceramic layer on the base; and
a second ceramic layer above the first ceramic layer,
wherein the first ceramic layer has
a first base portion made of a first ceramic, and
a plurality of heater electrodes included in the first base portion and for adjusting a temperature of the substrate, and
wherein the second ceramic layer has
a second base portion made of a second ceramic different from the first ceramic, and
a chucking electrode included in the second base portion and for holding the substrate.

2. The substrate support of claim 1, wherein the first base portion includes a plurality of areas, and
at least one of the plurality of heater electrodes are arranged in each of the plurality of areas.

3. The substrate support of claim 1, wherein the first ceramic layer includes a plurality of multi-layered electrical wirings included in the first base portion and connected to the plurality of heater electrodes, respectively.

4. The substrate support of claim 1, wherein the first base portion is a multi-layered structure in which a plurality of ceramic layers are stacked, and
at least one heater electrode is disposed between respective layers of the plurality of ceramic layers.

5. The substrate support of claim 4, wherein the plurality of ceramic layers is a sintered body of a plurality of green sheets.

6. The substrate support of claim 1, wherein the second base portion is a sintered body of the second ceramic.

7. The substrate support of claim 1, wherein the second ceramic has higher volume resistance than the first ceramic.

8. The substrate support of claim 1, comprising an adhesive layer including an inorganic adhesive and disposed between the first ceramic layer and the second ceramic layer.

9. The substrate support of claim 1, wherein the first ceramic and the second ceramic have the same ceramic as a main ingredient.

10. The substrate support of claim 1, wherein the second ceramic has higher purity than the first ceramic.

11. The substrate support of claim 1, wherein the second base portion has volume resistance of 1×10¹⁶Ω or more at a room temperature or more and 350° C. or less.

12. The substrate support of claim 1, wherein the second ceramic includes alumina at a mass percentage concentration of 99.95% or more.

13. The substrate support of claim 1, wherein a dielectric constant of the second ceramic is 10 to 11.

14. The substrate support of claim 1, wherein a difference in thermal expansion coefficients between the first base portion and the second base portion is 5 ppm or less.

15. The substrate support of claim 1, wherein the second ceramic has a porous rate of 0.1% or less.

16. A plasma processing apparatus processing a substrate, comprising:
a chamber; and
a substrate support inside the chamber,
wherein the substrate support has
a base,
a first ceramic layer on the base, and
a second ceramic layer above the first ceramic layer,
wherein the first ceramic layer has
a first base portion made of a first ceramic, and
a plurality of heater electrodes included in the first base portion and for adjusting a temperature of the substrate, and
wherein the second ceramic layer has
a second base portion made of a second ceramic different from the first ceramic, and
a chucking electrode included in the second base portion and for holding the substrate.

17. The plasma processing apparatus of claim 16, wherein the first base portion includes a plurality of areas, and
at least one of the plurality of heater electrodes are arranged in each of the plurality of areas.

18. The plasma processing apparatus of claim 16, wherein the first ceramic layer includes a plurality of multi-layered electrical wirings included in the first base portion and connected to the plurality of heater electrodes, respectively.

19. The plasma processing apparatus of claim 18, comprising at least one power supply connected to the plurality of heater electrodes through the plurality of multi-layered electrical wirings,
wherein each of the plurality of heater electrodes is configured to perform temperature control independently.

20. A plasma processing method processing a substrate using a plasma processing apparatus, wherein the plasma processing apparatus includes
a chamber, and
a substrate support disposed inside the chamber,
the substrate support has
a base,
a first ceramic layer on the base, and
a second ceramic layer above the first ceramic layer,
the first ceramic layer has
a first base portion made of a first ceramic, and
a plurality of heater electrodes included in the first base portion and for adjusting a temperature of the substrate, and
the second ceramic layer has
a second base portion made of a second ceramic different from the first ceramic, and
a chucking electrode included in the second base portion and for holding the substrate,
wherein the plasma processing method includes:
disposing the substrate on a substrate support surface of the substrate support;
chucking the substrate on the substrate support surface by using the chucking electrode;
heating the second ceramic layer and the substrate by using at least one of the plurality of heater electrodes to adjust a temperature of a partial area or an entire area of the substrate to 300° C. or more; and
plasma-processing the partial area or the entire area of the substrate of which the temperature is adjusted.
